(19) United States
(12) Patent Application Publication
(10) Pub. No.: US 2026/0136961 A1
(43) Pub. Date: May 14, 2026

(54) Conformally Plated TGVs Filled with Conductive Plug Materials

(71) Applicant: Intel Corporation, Santa Clara, CA (US)

(72) Inventors: Joshua STACEY, Chandler, AZ (US); Thomas HEATON, Gilbert, AZ (US); Joseph PEOPLES, Gilbert, AZ (US); Mahdi MOHAMMADIGHALENI, Phoenix, AZ (US); Whitney BRYKS, Tempe, AZ (US)

(21) Appl. No.: 18/945,597

(22) Filed: Nov. 13, 2024

(51) Int. Cl. H01L 23/498; H01L 21/48; H01L 23/14; H05K 1/11

(52) U.S. Cl. CPC H10W 70/635; H05K 1/111; H10W 70/095; H10W 70/695

(57) ABSTRACT

According to the various aspects, a present device may include a plurality of through hole via interconnects that are made of at least two conductive materials, which includes a conformally plated cooper layer enclosing a plug/filling of a low modulus conductive epoxy composite material to form dual material interconnects. The present dual material interconnects may reduce thermally-induced stresses on a glass substrate, as compared with the materials used in conventional through hole via interconnects.

### BACKGROUND

As semiconductor technology advances, the need to improve performance and lower costs for integrated circuit design and fabrication are constant challenges. It is becoming more difficult and costly to realize high-volume manufacturing for semiconductors as transistors continue to shrink in size. Cost savings may be potentially realized by building more efficient structures and using materials that improve power performance.

In terms of dimensional and performance stability, silicon and glass are better suited for fine-pitch interconnects with high input/output (I/O) density than organic substrates. However, as a semiconductor interconnect structure, silicon may require the deposition of dielectric layers, which raises production costs. On the other hand, as an insulating material, glass has become an attractive support material for advanced manufacturing and packaging due to its adjustable coefficient of thermal expansion (CTE), excellent surface flatness, high resistivity, and low cost. Therefore, glass has emerged as the material of choice in recent years for a new generation of semiconductor devices.

It is common to use through-glass-vias (TGVs) and microvias as the interconnects between layers in high-density interconnect substrates and printed circuit boards (PCBs) to accommodate the high I/O density of advanced packages. The use of three-dimensional (3D) interconnects with TGV technology has wide applicability in radio frequency (RF) devices, optoelectronic systems, and multi-layer glass substrates. However, the conductive materials, such as copper (Cu), used to form a TGV interconnect may expand/shrink inside the through hole vias causing stresses on the glass substrate, which may lead to their failure. For example, a TGV- Cu structure may have induced stress inside the TGV after undergoing high-temperature processes or reliability evaluations, which leads to glass cracking due to a mismatch between the different CTEs of the materials. It is therefore important to have solutions that are able to improve a TGV interconnect's structure for advanced packages and improve the mechanical performance/stability of the through hole via connections.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1 and 1A show an exemplary representation of a device with through hole via interconnects made of two conductive materials according to an aspect of the present disclosure;

FIGS. 2A through 2D show exemplary representations of the formation of a device with dual material connects according to an aspect of the present disclosure; and

FIG. 3 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to various aspects of this disclosure, a present device may include a plurality of through hole via interconnects that are made of at least two conductive materials, which includes a conformal metal layer (e.g., copper) enclosing a plug/filling of a low modulus conductive material (e.g., a resin) to form dual material interconnects. The present dual material interconnects may reduce thermally-induced stresses on a glass substrate, as compared with the materials used in conventional through hole via interconnects. In an aspect, an understanding of the power delivery requirements for a device may enable a determination and the use of minimum thicknesses for the plated metal layers for the plurality of dual material interconnects. The use of thinner metal layers may lower the stress on the glass substrate without compromising the electrical performance of the device.

The present disclosure provides a device including a substrate with dual material interconnects disposed in a plurality of through hole vias formed in the substrate connecting a top surface and a backside surface of the substrate. In an aspect, the dual material interconnects have a metal layer surrounding a central core, for which the central core includes a low modulus conductive material, and are configured to provide at least a minimum power delivery requirement for the device. In an aspect, the metal layer may be a copper layer and the central core may be an epoxy composite resin.

The present disclosure is also directed to a method that includes determining the power delivery requirements for a design having a plurality of through hole via interconnects, determining a minimum metal lining thickness for the plurality of through hole via interconnects using the power delivery requirements, providing a substrate having a top surface and a backside surface and forming a plurality of through hole vias disposed in the substrate, and forming metal linings in the plurality of through hole vias. In an aspect, the forming of the metal linings in the plurality of through hole vias includes providing a metal seed layer and a metal conducting layer on the sidewall surfaces of each of the plurality of through hole vias. After the the metal linings are formed, the method further includes filling the central hollow portions with a low modulus conductive material to form a conductive central core. The metal linings and the low modulus conductive material form a plurality of dual material interconnects in the substrate.

In an aspect, the metal linings are configured to have thicknesses that are at least equal to or greater than the minimum metal lining thickness and to retain central hollow portions in the plurality of through hole vias. In an aspect, the minimum metal lining thickness may be in the range of approximately 10 percent of a TGC interconnect diameter. In another aspect, the metal seed layers are formed using an electrolytic process or thin-film deposition process and the metal conducting layers are formed using a metal plating process or other conventional metal deposition processes.

The present disclosure is further directed to a product made by a process that includes providing a substrate having a top surface and a backside surface and forming a plurality of through hole vias disposed in the substrate, forming copper linings in the plurality of through hole vias, for which the copper linings are configured to have thicknesses that are at least equal to or greater than a minimum copper lining thickness for the product and retain central hollow portions in the plurality of through hole vias, and filling the central hollow portions with a low modulus conductive material, for which the copper linings and the low modulus conductive material form a plurality of dual material interconnects in the substrate for the product.

The technical advantages of the present disclosure include, but are not limited to:
(i) providing improved mechanical performance and stability of through hole via interconnects formed in glass substrates by damping and distributing the stresses on the glass substrates caused by expansion/shrinkage of a conductive material, e.g., copper, used in the through hole via interconnects by providing a central core in the through hole via interconnects made of a low modulus conductive material;
(ii) providing for thinner conformally plated metal linings on through glass via (TGV) sidewalls by providing an additional conductive path through the central cores of the TGV interconnect rather than relying solely on the conformally plated metal lining; and
(iii) providing methods for forming interconnects in the through hole vias that are compatible with high-volume manufacturing requirements.

To more readily understand and put into practical effect the present devices with through hole via interconnects having polymer linings in the vias and methods for their manufacture, which may provide improved substrates in the devices, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

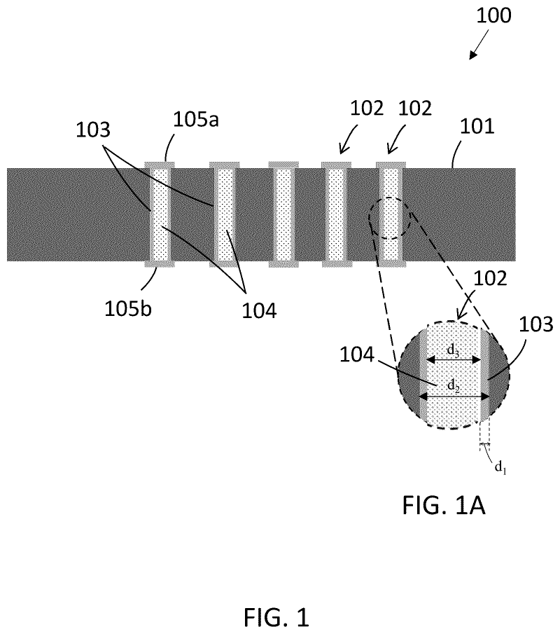

FIGS. 1 and 1A show an exemplary representation of a present device 100 with a plurality of through hole via interconnects 102 made of two conductive materials according to an aspect of the present disclosure. In this aspect, the device 100 may have a glass substrate 101, which may be part of a larger glass panel. The through hole via interconnects 102 (which are also called dual material interconnects herein) may be made of a conductive material or metal layer 103, such as copper (Cu), that surrounds a central core 104 that may be made of a low modulus conductive material, such as an epoxy composite. The central core 104 may be able to share part of the conductive load with the metal layer 103. In another aspect, the plurality of through hole via interconnects 102 may be coupled to a first contact pad 105a and a second contact pad 105b.

The present through hole via interconnects being configured using two or more conductive materials, including a low modulus material for the central core, that may provide improved mechanical performance and stability for through hole via interconnects in semiconductor devices by damping the stresses on the vias caused by expansion of the through hole via interconnects. In an aspect, the plurality of dual material interconnects may be disposed in selected zones on the substrate that are found to undergo greater thermally induced stresses or other physical stresses, while other zones are provided with conventional through hole via interconnects.

In an aspect, the metal layer 103 may be made of, for example, copper, aluminum, silver, gold, or other conductive metals. In another aspect, the metal layer 103 may be a combination of two or more layers of conductive metals.

In an aspect, the central core 104 may be made of a softer material with a lower modulus of elasticity than the metal layer 103 to provide a rubber-like property; namely, it may deform but recover its shape. In an aspect, the central core 104 may have a low modulus in the range of approximately 30 gigapascal (GPa). For example, the central core 104 may be made of a conventional epoxy composite having metal nanoparticles, such as silver particles, copper particles, etc. To provide the desired conductive properties, for example, the metal nanoparticles may have a loading of greater than 70 percent.

In another aspect, for example, the central core 104 may be made of a conventional epoxy composite having carbon nanotubes. To provide the desired conductive properties, for example, the carbon nanotubes may have a loading of greater than 70 percent.

In yet another aspect, for example, the central core 104 may be made of a thermal interface material (TIM), which includes relatively soft and compliant metal alloys, such as silver pastes, and other TIM gels/pastes.

As shown in FIG. 1A, the metal layer 103 may have a thickness dimension “d₁”. The power delivery requirements for the device 100 will be understood from the device design and would enable a determination of a minimum thickness “d₁” for the metal layers 103 for the plurality of dual material interconnects 102. For example, a minimum thickness “d₁” may have a range of approximately 5 μm to 20 μm. The metal layer 103 may be thinner than used in conventional through hole via interconnects because the core 104 may be able to share part of the conductive load for the device 100. The present use of thinner metal layers 103 may lower the stress on the glass substrate 101 without compromising the electrical performance of the device 100.

In another aspect, the through hole via interconnects 102 may have a cross-sectional dimension “d₂” and the central core 104 may have a cross-sectional dimension “d₃”. For example, the cross-sectional dimension “d₃” may have a range of approximately 20 to 80 percent of the cross-sectional dimension “d₂”, depending on the power requirements of the device 100.

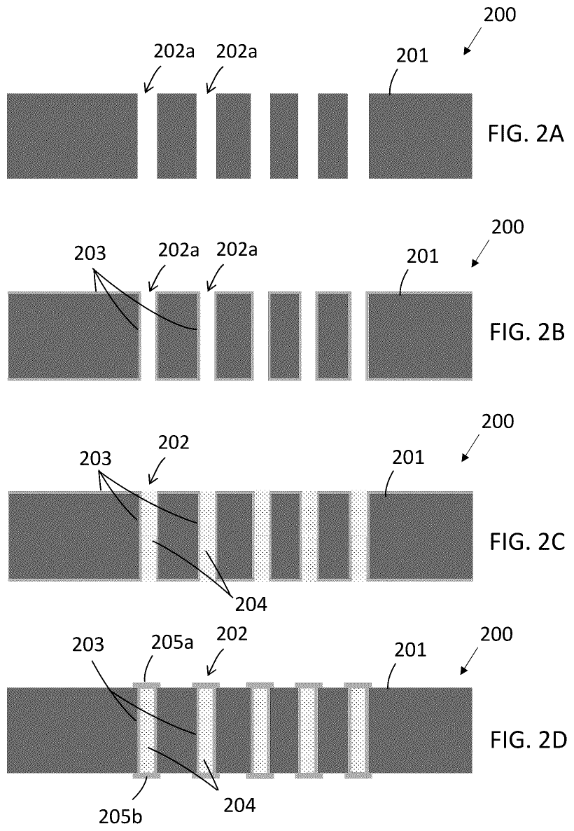

FIGS. 2A through 2D show exemplary representations of the formation of a device 200 according to an aspect of the present disclosure. In this aspect, as shown in FIG. 2A, a glass substrate 201 may have a plurality of through glass vias (TGVs) 202a for forming a plurality of dual material interconnects 202.

In FIG. 2B, the plurality of TGVs 202a may be lined with a metal layer 203. In aspect, the metal layer 203 may formed by initially depositing a thin metal seed layer (not shown) and followed by a thicker metal conducting layer (not shown) on sidewall surfaces of each of the plurality of TGVs 202a. In an aspect, the thin seed layer may be deposited using a conventional electrolytic process or a thin-film deposition process, such as plasma vapor deposition or atomic layer deposition. In an aspect, the metal conducting layer may be deposited using a conventional metal plating process or vacuum depositon processes like atomic layer depositon (ALD).

In FIG. 2C, the plurality of TGVs 202a with the metal lining 203 may be further filled with a low modulus conductive material, e.g., an epoxy composite, to form a conductive central core 204. In an aspect, a conventional coating process may be used to fill the plurality of metal lined TGVs 202a, such as blade coating, screen printing, doctor blade coating, spray coating, squeegee coating, dip coating, spinning coating, roll coating, vacuum filling, and other coating methods.

For through hole vias with aspect ratios that are greater than 10:1 (substrate thickness vs via diameter), it may be preferable to use an electro-hydro-dynamic-force (EHDF) filling method. When using EHDF methods, the present low modulus conductive material may be “pulled” by an electric field into the through hole vias, for example, by a direct current (DC) charge generated between electrodes. The low modulus conductive material may be, for example, dropped or sprayed onto a substrate, with a first electrode above and another second electrode beneath the substrate.

In FIG. 2D, the device 200 may have a first conductive layer (not shown) deposited on the top surface of the substrate 201 and the first conductive layer may be etched to form first contact pads 205a that are coupled to the plurality of dual material interconnects 202. The substrate 201 may be turned over and a second conductive layer (not shown) may be deposited on the backside surface of the substrate and etched to form second contact pads 205b that coupled to the plurality of dual material interconnects. In an aspect, the first and second conductive layers may be made of copper or another conductive metal.

FIG. 3 shows a simplified flow diagram for an exemplary method according to an aspect of the present disclosure.

The operation 301 may be directed to providing a substrate with a plurality of through hole vias.

The operation 302 may be directed to depositing copper linings in the through hole vias to form dual material interconnects.

The operation 303 may be directed to filling the through hole vias with a conductive material to form dual material interconnects.

The operation 304 may be directed to depositing copper layers over the top and backside surfaces of the substrate.

The operation 304 may be directed to etching the copper layers to form contact pads for the interconnects.

It will be understood that any property described herein for a particular device with through hole via interconnects having metal linings surrounding a conductive central core (i.e., dual material interconnects) in the vias and/or method for forming the dual material interconnects may also hold for any devices using the present methods described herein. It will also be understood that any property described herein for a specific method may hold for any of the methods described herein. Furthermore, it will be understood that for any device and the methods described herein, not necessarily all the components or operations described will be shown in the accompanying drawings or method, but only some (not all) components or operations may be disclosed.

To more readily understand and put into practical effect the present devices with through hole via interconnects having polymer linings in the vias and present methods for forming the devices having present polymer linings, they will now be described by way of examples. For the sake of brevity, duplicate descriptions of features and properties may be omitted.

### EXAMPLES

Example 1 provides a device including a substrate with dual material interconnects disposed in a plurality of through hole vias formed in the substrate connecting a top surface and a backside surface of the substrate. The dual material interconnects have a metal layer surrounding a central core, for which the central core includes a low modulus conductive material, and are configured to provide at least a minimum power delivery requirement for the device.

Example 2 may include the device of example 1 and/or any other example disclosed herein, for which the low modulus conductive material includes an epoxy composite having metal nanoparticles.

Example 3 may include the device of example 1 and/or any other example disclosed herein, for which the low modulus conductive material includes an epoxy composite having carbon nanotubes.

Example 4 may include the device of example 1 and/or any other example disclosed herein, for which the low modulus conductive material includes a thermal interface material.

Example 5 may include the device of example 1 and/or any other example disclosed herein, which further includes a first contact pad disposed at the top surface and a second contact pad disposed at the backside surface the substrate for each of the plurality of dual material interconnects.

Example 6 may include the device of example 1 and/or any other example disclosed herein, for which the plurality of dual material interconnects are disposed in selected zones on the substrate.

Example 7 provides a method that includes determining power delivery requirements for a plurality of through hole via interconnects for a device, determining a minimum metal lining thickness for the plurality of through hole via interconnects using the power delivery requirements, providing a substrate having a top surface and a backside surface and forming a plurality of through hole vias disposed in the substrate, forming metal linings in the plurality of through hole vias, for which the metal linings are configured to have thicknesses that are at least equal to or greater than the minimum metal lining thickness and retain central hollow portions in the plurality of through hole vias, and filling the central hollow portions with a low modulus conductive material to form a central core, for which the metal linings and the low modulus conductive material form a plurality of dual material interconnects in the substrate.

Example 8 may include the method of example 7 and/or any other example disclosed herein, for which the forming of the metal linings in the plurality of through hole vias further includes providing a metal seed layer and a metal conducting layer on sidewall surfaces of each of the plurality of through hole vias.

Example 9 may include the method of example 8 and/or any other example disclosed herein, for which the metal seed layers are formed using an electrolytic process or thin-film deposition process.

Example 10 may include the method of example 8 and/or any other example disclosed herein, for which the metal conducting layers are formed using a metal plating process.

Example 11 may include the method of example 7 and/or any other example disclosed herein, for which the filling of the central hollow portions with a low modulus conductive material further includes using a coating method.

Example 12 may include the method of example 7 and/or any other example disclosed herein, for which the filling of the central hollow portions with a low modulus conductive material further includes using an electro-hydro-dynamic-force filling method.

Example 13 may include the method of example 7 and/or any other example disclosed herein, which further includes depositing a first conductive layer on the top surface of the substrate and etching the first conductive layer to form first contact pads coupled to the plurality of dual material interconnects, and depositing a second conductive layer on the backside surface of the substrate and etching the second conductive layer to form second contact pads coupled to the plurality of dual material interconnects.

Example 14 provides a product made by a process that includes providing a substrate having a top surface and a backside surface and forming a plurality of through hole vias disposed in the substrate, forming copper linings in the plurality of through hole vias, for which the copper linings are configured to have thicknesses that are at least equal to or greater than a minimum copper lining thickness for the product and retain central hollow portions in the plurality of through hole vias, and filling the central hollow portions with a low modulus conductive material, for which the copper linings and the low modulus conductive material form a plurality of dual material interconnects in the substrate for the product.

Example 15 may include the product of example 14 and/or any other example disclosed herein, for which the process of forming the copper linings in the plurality of through hole vias further includes providing a copper seed layer and a copper conducting layer on sidewall surfaces of each of the plurality of through hole vias.

Example 16 may include the product of example 15 and/or any other example disclosed herein, for which the process of forming the copper seed layers uses an electrolytic process or a thin-film deposition process.

Example 17 may include the product of example 15 and/or any other example disclosed herein, for which the process of forming the copper conducting layers uses a copper plating process.

Example 18 may include the product of example 14 and/or any other example disclosed herein, for which the process of filling the central hollow portions with the low modulus conductive material further includes using a coating method.

Example 19 may include the product of example 14 and/or any other example disclosed herein, for which the process of filling the central hollow portions with the low modulus conductive material further includes using an electro-hydro-dynamic-force filling method.

Example 20 may include the product of example 14 and/or any other example disclosed herein, for which the process further includes depositing a first copper layer on the top surface of the substrate and etching the first copper layer to form first contact pads coupled to the plurality of dual material interconnects, and depositing a second copper layer on the backside surface of the substrate and etching the second copper layer to form second contact pads coupled to the plurality of dual material interconnects.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a substrate comprising dual material interconnects disposed in a plurality of through hole vias formed in the substrate connecting a top surface and a backside surface of the substrate, wherein the dual material interconnects comprise:
a metal layer surrounding a central core, wherein the central core comprises a low modulus conductive material, and wherein the dual material interconnects are configured to provide at least a minimum power delivery requirement for the device.

2. The device of claim 1, wherein the low modulus conductive material comprises an epoxy composite having metal nanoparticles.

3. The device of claim 1, wherein the low modulus conductive material comprises an epoxy composite having carbon nanotubes.

4. The device of claim 1, wherein the low modulus conductive material comprises a thermal interface material.

5. The device of claim 1, further comprising a first contact pad disposed at the top surface and a second contact pad disposed at the backside surface the substrate for each of the plurality of dual material interconnects.

6. The device of claim 1, wherein the plurality of dual material interconnects are disposed in selected zones on the substrate.

7. A method comprising:
determining power delivery requirements for a plurality of through hole via interconnects for a device;
determining a minimum metal lining thickness for the plurality of through hole via interconnects using the power delivery requirements;
providing a substrate having a top surface and a backside surface and forming a plurality of through hole vias disposed in the substrate;
forming metal linings in the plurality of through hole vias, wherein the metal linings are configured to have thicknesses that are at least equal to or greater than the minimum metal lining thickness and retain central hollow portions in the plurality of through hole vias; and
filling the central hollow portions with a low modulus conductive material to form a central core, wherein the metal linings and the low modulus conductive material form a plurality of dual material interconnects in the substrate.

8. The method of claim 7, wherein the forming of the metal linings in the plurality of through hole vias further comprises providing a metal seed layer and a metal conducting layer on sidewall surfaces of each of the plurality of through hole vias.

9. The method of claim 8, wherein the metal seed layers are formed using an electrolytic process or thin-film deposition process.

10. The method of claim 8, wherein the metal conducting layers are formed using a metal plating process.

11. The method of claim 7, wherein the filling of the central hollow portions with a low modulus conductive material further comprises using a coating method.

12. The method of claim 7, wherein the filling of the central hollow portions with a low modulus conductive material further comprises using an electro-hydro-dynamic-force filling method.

13. The method of claim 7, further comprises:
depositing a first conductive layer on the top surface of the substrate and etching the first conductive layer to form first contact pads coupled to the plurality of dual material interconnects; and
depositing a second conductive layer on the backside surface of the substrate and etching the second conductive layer to form second contact pads coupled to the plurality of dual material interconnects.

14. A product made by a process comprising:
providing a substrate having a top surface and a backside surface and forming a plurality of through hole vias disposed in the substrate;
forming copper linings in the plurality of through hole vias, wherein the copper linings are configured to have thicknesses that are at least equal to or greater than a minimum copper lining thickness for the product and retain central hollow portions in the plurality of through hole vias; and
filling the central hollow portions with a low modulus conductive material, wherein the copper linings and the low modulus conductive material form a plurality of dual material interconnects in the substrate for the product.

15. The product of claim 14, wherein the process of forming the copper linings in the plurality of through hole vias further comprises providing a copper seed layer and a copper conducting layer on sidewall surfaces of each of the plurality of through hole vias.

16. The product of claim 15, wherein the process of forming the copper seed layers uses an electrolytic process or a thin-film deposition process.

17. The product of claim 15, wherein the process of forming the copper conducting layers uses a copper plating process.

18. The product of claim 14, wherein the process of filling the central hollow portions with the low modulus conductive material further comprises using a coating method.

19. The product of claim 14, wherein the process of filling the central hollow portions with the low modulus conductive material further comprises using an electro-hydro-dynamic-force filling method.

20. The product of claim 14, wherein the process further comprises:
depositing a first copper layer on the top surface of the substrate and etching the first copper layer to form first contact pads coupled to the plurality of dual material interconnects; and
depositing a second copper layer on the backside surface of the substrate and etching the second copper layer to form second contact pads coupled to the plurality of dual material interconnects.
